(19) United States
(12) Patent Application Publication
(10) Pub. No.: US 2008/0216493 A1
(43) Pub. Date: Sep. 11, 2008

(54) MICROCHANNEL COOLING CONDENSER FOR PRECISION COOLING APPLICATIONS

(75) Inventors: Wanlai LIN, Dublin, OH (US); Liangyin DING, Shenzhen (CN); Peter Geoffrey JOLLY, Shenzhen (CN); John F. JUDGE, Galena, OH (US); Steven M. MADARA, Dublin, OH (US)

Correspondence Address: LOCKE LORD BISSELL & LIDDELL LLP;ATTN: IP DOCKETING, 600 TRAVIS STREET, 3400 CHASE TOWER, HOUSTON, TX, 77002, US

(73) Assignee: LIEBERT CORPORATION, Columbus, OH (US)

(21) Appl. No.: 11/972,012

(22) Filed: Jan. 10, 2008

Related U.S. Application Data
(60) Provisional application No. 60/893,745, filed on Mar. 8, 2007.

(51) Int. Cl. H05K 7/20; F25B 1/00

(52) U.S. Cl. 62/115; 62/259.1; 62/498

(57) ABSTRACT

The present disclosure provides a method, apparatus, and system for a centralized microchannel cooling system in precision cooling applications, such as mission-critical systems with data centers or cabinets or rooms with medical equipment. The microchannel condenser is designed to provide sufficient cooling for such applications by configuring multiple microchannel slabs together in a fashion that advantageously can increase the overall cooling abilities of multiple slabs not heretofore known. The system can provide a retrofit condenser for some existing precision cooling systems that have limitations on size, while satisfying cooling capacity requirements. The multiple slabs can be cooled by flowing a fluid such as air or a liquid across them. One or more microchannel slabs can be mounted horizontally, vertically, or in an inclined position. Further, the system can allow for multiple passes of refrigerants through the microchannel slabs.

### CROSS REFERENCE TO RELATED APPLICATIONS

This application claims the benefit of U.S. Provisional Application Ser. No. 60/893,745, filed Mar. 8, 2007, which is incorporated by reference.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO APPENDIX

Not applicable.

### BACKGROUND

1. Field of the Invention

The invention relates to micro-channel cooling. More specifically, the invention relates to micro-channel cooling for electronics cooling rooms and cabinets in precision cooling applications.

2. Description of Related Art

Increased demands are being made on cooling systems for electronic equipment in precision cooling applications. Precision cooling applications include mission-critical systems, such as data centers with cooled rooms and cooled cabinets for electronic equipment, medical equipment centers and operating rooms, and the like. If the equipment is not sufficiently cooled, the internal temperature of the electronic components in the equipment dramatically increases over relatively short periods of time, which may result in significantly reduced system performance and, in some cases, component or total system failure. The additional power and capabilities combined with increased density of electronics placement have stressed the capabilities of conventional cooling schemes for such precision cooling applications. Even where system performance is not compromised, inefficient cooling may unnecessarily increase the cost of cooling the equipment and shorten the lifetime of the equipment.

Typically, a refrigeration system uses conventional fin-and-tube condenser coils to dissipate heat generated from other portions of the refrigeration system, such as the compressor and evaporator, by passing the refrigerant through the condenser coils. The refrigerant is then circulated back to other system portions in a closed loop system. The condenser coil must be sized to absorb the heat for the system to maintain continuous operation. However, fin-and-tube condenser coils often have poor efficiencies in dissipating heat from the refrigerant passing through the coils. As a result, fin-and-tube condenser coils can be disproportionately large for the amount of heat they can dissipate from the refrigerant. The size also increases the amount of refrigerant which can have an environmental impact.

New and different methods are being investigated to increase the cooling capabilities to satisfactory levels. A recent innovation is the use of microchannel cooling technology to provide increase efficiencies. Microchannel technology uses cooling tubes subdivided into multiple channels for separating the cooling fluid into individual flow paths and increased energy transfer. A typical application for microchannel cooling has been in conduction cooling of electronic chips. An example is U.S. Pat. No. 6,903,929 in which an integrated circuit is thermally coupled to a pair of microchannel heat exchangers disposed on opposite sides of an integrated circuit die to cool the electronic components. Another example is seen in U.S. Pat. No. 6,986,382 in which a microchannel heat exchanger captures thermal energy generated from a heat source by passing fluid through selective areas of the interface layer that is preferably coupled to the heat source, such as electronic chips. In particular, the fluid is directed to specific areas in the interface layer to cool the hot spots and areas around the hot spots to create temperature uniformity across the heat source while maintaining a small pressure drop within the heat exchanger. A more recent application of microchannel technology has been applied to specific racks in cooling cabinets in U.S. Publ. No. 2006/0102322. At least one embodiment discusses a plurality of heat-generating objects, such as electronic circuit boards and hardware, that are situated vertically in an electronic cabinet or other enclosure, and a plurality of heat exchangers that are situated in the enclosure such that a heat exchanger is situated between adjacent heat generating objects in a spaced-apart relationship.

However, these examples are for cooling the electronic device or other source of heat in a specific portion of the refrigeration system, typically known as an “evaporator.” Different parameters apply for cooling the refrigerant by dissipating the heat of the cooling fluid in the refrigeration system portion typically known as the “condenser.” One microchannel application for a condenser portion of the refrigeration system is seen in U.S. Pat. No. 6,988,538 in which a condenser assembly can condense an evaporated refrigerant for use in a retail store refrigeration system. The condenser assembly includes at least one microchannel condenser coil including an inlet manifold and an outlet manifold. The patent discloses serial and parallel flow path arrangements of multiple microchannel condensers, and stacked and single layer systems of condensers.

Thus, there remains a need for a centralized microchannel cooling system for precision cooling applications.

### BRIEF SUMMARY

The present disclosure provides a method, apparatus, and system for a centralized microchannel cooling system in precision cooling applications, such as mission-critical systems with data centers or cabinets or rooms with medical equipment. The microchannel condenser is designed to provide sufficient cooling for such applications by configuring multiple microchannel slabs together in a fashion that advantageously can increase the overall cooling abilities of multiple slabs not heretofore known. The system can provide a retrofit condenser for some existing precision cooling systems that have limitations on size, while satisfying cooling capacity requirements. The multiple slabs can be cooled by flowing a fluid such as air or a liquid across them. One or more microchannel slabs can be mounted horizontally, vertically, or in an inclined position. Further, the system can allow for multiple passes of refrigerants through the microchannel slabs.

The disclosure provides a cooling system for precision cooling for electronic equipment, comprising: an electronic equipment support structure adapted to support one or more heat generating electronic equipment; an evaporator in fluid communication with the support structure and adapted to provide cooling to the support structure; a compressor; and a microchannel condenser fluidicly coupled to the compressor and adapted to cool refrigerant from the compressor and dissipate heat from the refrigerant.

The disclosure further provides a method of precision cooling for electronic equipment, comprising: flowing a quantity of refrigerant through an evaporator to cool heat generating electronic equipment supported in an electronic equipment support structure; compressing the refrigerant through a compressor; cooling the refrigerant through a microchannel condenser; and flowing a quantity of air across fins in the microchannel condenser.

### BRIEF DESCRIPTION OF THE DRAWINGS

While the concepts provided herein are susceptible to various modifications and alternative forms, only a few specific embodiments have been shown by way of example in the drawings and are described in detail below. The figures and detailed descriptions of these specific embodiments are not intended to limit the breadth or scope of the concepts or the appended claims in any manner. Rather, the figures and detailed written descriptions are provided to illustrate the concepts to a person of ordinary skill in the art as required by 35 U.S.C. § 112.

FIG. 1 is a perspective schematic diagram of an exemplary precision cooling application.

FIG. 2 is a perspective schematic diagram of an exemplary refrigeration system.

FIG. 3 is a top schematic diagram of an exemplary microchannel condenser system using multiple microchannel slabs with multiple flow paths of refrigerant.

FIG. 4 is a top schematic diagram of an exemplary microchannel condenser system using multiple microchannel slabs cooled with a single fan.

FIG. 5 is a top schematic diagram of an exemplary microchannel condenser system using multiple microchannel slabs with a parallel flow path of refrigerant in serial communication with at least one other microchannel slab.

FIG. 6 is a top schematic diagram of an exemplary microchannel slab with exemplary dimensions.

FIG. 7 is a top schematic diagram of an exemplary multi-path microchannel slab with exemplary dimensions for flowing multiple passes of refrigerant through the slab.

FIG. 8 is a side schematic diagram of an exemplary microchannel slab.

FIG. 9 is a cross-sectional schematic diagram of an exemplary microchannel tube illustrating micro channels formed in the tube.

FIG. 10 is a cross-sectional schematic diagram of an exemplary cooling fin that can be coupled to at least one microchannel tube.

FIG. 11 is a top schematic diagram of an exemplary slab refrigeration system.

FIG. 12 is a top schematic diagram of an exemplary multiple slab refrigeration system in a parallel flow path with multiple condenser fans.

FIG. 13 is a top schematic diagram of an exemplary multiple slab refrigeration system in a serial flow path with multiple condenser fans.

FIG. 14 is a top schematic diagram of an exemplary slab refrigeration system with multiple condenser fans.

### DETAILED DESCRIPTION

One or more illustrative embodiments of the concepts disclosed herein are presented below. Not all features of an actual implementation are described or shown in this application for the sake of clarity. It is understood that the development of an actual embodiment, numerous implementation-specific decisions must be made to achieve the developer's goals, such as compliance with system-related, business-related, and other constraints, which vary by implementation and from time to time. While a developer's efforts might be complex and time-consuming, such efforts would be, nevertheless, a routine undertaking for those of ordinary skill in the art having benefit of this disclosure.

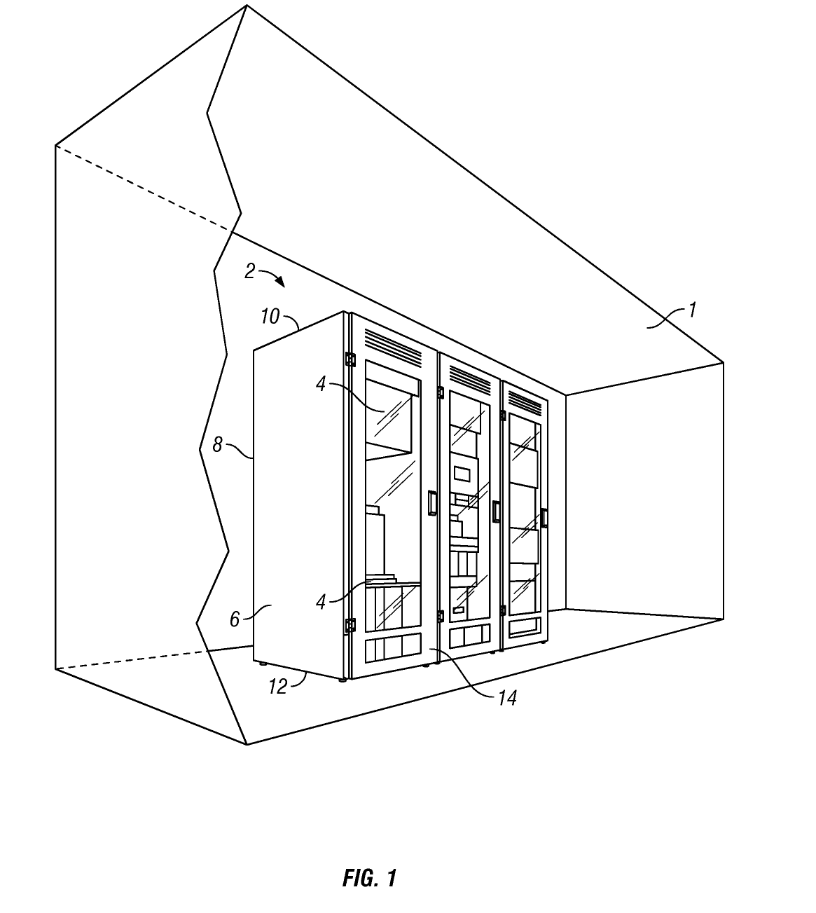

FIG. 1 is a perspective schematic diagram of an exemplary precision cooling application. Precision cooling applications in electronic equipment support structures, such as a cooled room 1 and/or a cooled electronic cabinet 2, can benefit from the refrigeration system described herein. Electronic equipment is generally organized in the room 1 and often in a cabinet 2 with multiple horizontal trays 4 to support multiple rows of equipment. The cabinet 2 generally includes sides, 6, back 8, top 10, bottom 12, and a door 14 to gain access to the equipment therein. Power rails, uninterruptible power supplies, and other features can be included. Multiple cabinets can be placed in the cooling room 1 as is appropriate for the particular installation. If the refrigeration system is mounted in the room 1, the cooling fluid can be directed to an external location and be cooled through a condenser with the resultant heat dissipated outside the room. If the refrigeration system is mounted to the cooling cabinet 2, the condenser can be mounted to the cabinet and the heat dissipated to the room 1, where a separate cooling system can cool the room, or the cooling cabinet heat can be directed external to the room and the heat dissipated outside the room.

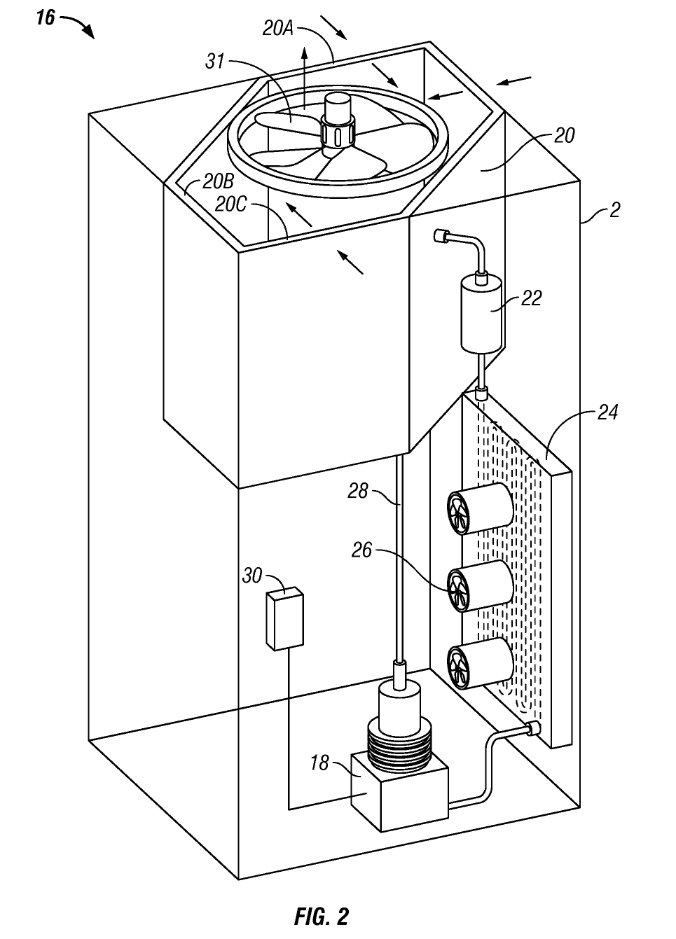

FIG. 2 is a perspective schematic diagram of an exemplary refrigeration system. While this embodiment illustrates a refrigeration system coupled with a cooled electronics cabinet, it is understood that the refrigeration system could be coupled with the room 1, described in FIG. 1, or other electronic equipment support structures. The refrigeration system 16 generally includes a compressor 18 for compressing refrigerant in the system to an elevated pressure, a condenser 20 to cool the refrigerant that is heated by the act of compression, an expansion device 22 that causes a pressure drop as the refrigerant flows therethrough and thermodynamically cools the refrigerant, an evaporator 24 that is cooled by the cooled refrigerant flowing therethrough, at least one fan 26 to move air across the evaporator's surfaces to cool the support structure and electronic equipment whereby the refrigerant in turn absorbs heat from the warmer air produced by the electronic equipment, various refrigerant lines 28 for carrying the refrigerant between the components, and a system controller 30, such as a thermostat. A condenser fan 31 is used to move air across cooling fins of the condenser 20 to cool the condenser and therefore cool the heated, compressed refrigerant, if the condenser system is an air cooled system. While the condenser system in the exemplary embodiments is described as an air cooled system, it should be appreciated that alternatively the condenser may be cooled by any fluid, such as gaseous mediums or liquids or any cooling method known to a person of ordinary skill in the art. For example, a pump may be used to move the fluid, such as a liquid, across the cooling fins of the condenser 20 to cool the condenser and therefore cool the heated, compressed refrigerant.

In at least one embodiment, the compressor 18 can be a fixed displacement compressor or advantageously a variable flow compressor, sometimes referred to as a modulated or digital scroll compressor. The variable flow compressor can allow the refrigeration system 16 to operate more efficiently in that the compressor can be modulated more closely to variable load conditions. For example, the modulation can be controlled by controlling the duty cycle of the compressor with a bypass valve that opens and closes to at least partially bypass the compression stage of the compressor.

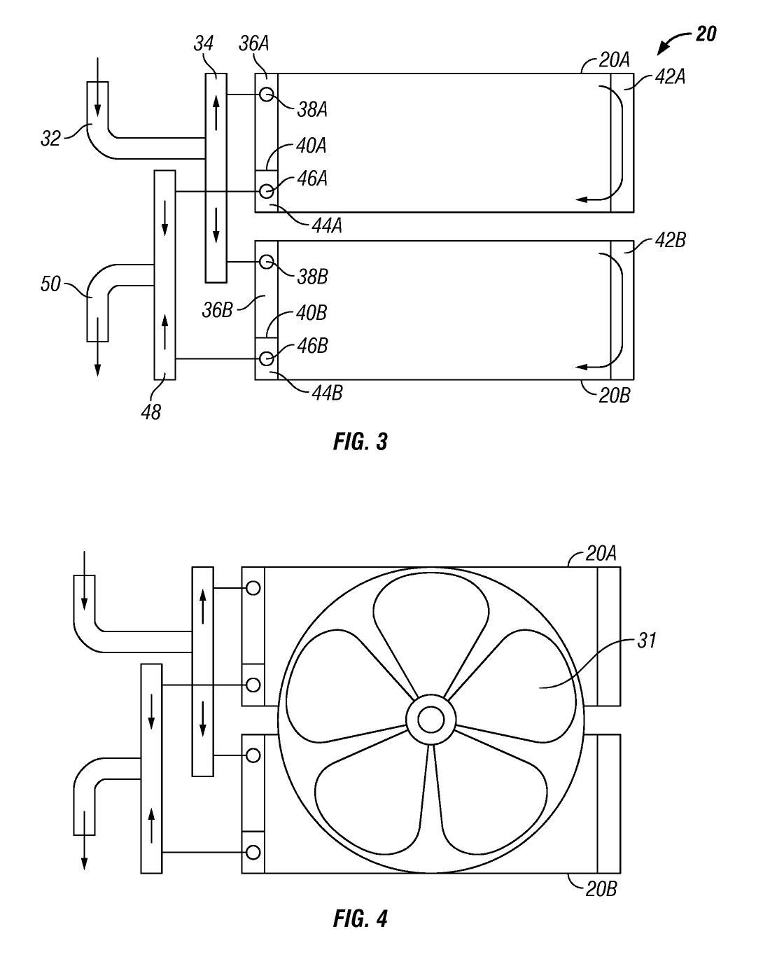

The condenser 20 is used to cool the refrigerant, heated by the compressor compressing the refrigerant. Generally, the condenser 20 can be subdivided into one or more modules (herein “slabs”), so that refrigerant can flow through each of the slabs to control the amount of cooling from the refrigerant and hence head pressure on the refrigeration system. The condenser 20 can include, therefore, microchannel slabs 20A, 20B, 20C. Further, it is understood that the slabs can be mounted vertically as illustrated in FIG. 2 or horizontally as illustrated in FIG. 3. Advantageously, if mounted horizontally, the vertical height of the cabinet 2 can be shortened or the same height can be used for other purposes such as additional support space for electronic equipment.

The expansion device 22, such as an expansion valve, can expand the refrigerant to a lower pressure and thermodynamically cool the refrigerant. The cooled refrigerant flows from the expansion device to the evaporator 24. The evaporator 24 is a heat exchanger that cools warmer air generated by the electronic equipment in the support structure and is therefore in fluid communication with the support structure. One or more fans 26 can move air across the surfaces of the evaporator 24 and increase the efficiency of the system 16. The evaporator 24 allows cool refrigerant flowing in the evaporator to cool warmer air or another medium flowing across the evaporator external surfaces. Conversely, the flowing medium transfers its higher heat into the refrigerant. In at least one embodiment, the evaporator 24 can be mounted vertically along the height of the cabinet 2.

The controller 30 can be used to control the flow of refrigerant through the system, the operation of the compressor, the operation of the fans, the operation of pumps, and other operational factors. Further, the controller 30 can control one or more valves (not shown) that control the flow of refrigerant through the condenser and particularly through one or more of the microchannel slabs.

FIG. 3 is a top schematic diagram of an exemplary microchannel condenser system using multiple microchannel slabs with multiple flow paths of refrigerant. A microchannel condenser 20 can be formed from a single slab or, as shown, multiple slabs 20A, 20B fluidicly coupled together. Further, in this embodiment and the other embodiments described herein, the microchannel slabs can be subdivided into smaller slabs. In at least one embodiment, the slabs can be coupled in parallel flow arrangements. Depending on the heat dissipation requirements, the number of microchannel slabs can vary from one to many slabs. In an advantageous embodiment, three (3) slabs can be coupled to form an effective size of about 40 inches by 40 inches. This particular size can be used to retrofit existing condenser system in some cooled electronic cabinets. Each slab has a plurality of microchannel tubes spaced apart at a pitch distance, which can vary depending on heat loads between the slabs and within each slab as necessary. Each microchannel tube has a plurality of microchannels formed within the tube to separate and conduct portions of the refrigerant flow through each tube. Further details are disclosed herein.

An inlet refrigerant line 32 can provide the refrigerant to the microchannel condenser. If multiple slabs are used, the line 32 can provide the refrigerant to an inlet manifold 34 that then can provide the refrigerant to the slabs. Each slab 20A, 20B can include an inlet header 36A, 36B. The inlet headers 36A, 36B can include slab inlets 38A, 38B, respectively, where the inlet manifold 34 can be fluidicly coupled to the slab inlets. The refrigerant can flow into the slab through the slab inlets 38A, 38B and flow into an intermediate header 42A, 42B on the slabs 20A, 20B. When the slab is a multi-path slab, so that the refrigeration passes multiple times therethrough, the intermediate headers 42A, 42B can return the flow of refrigerant into a return path through the slab to an outlet. Baffles 40A, 40B on the slabs 20A, 20B can be used to separate the inlet headers 36A, 36B from outlet headers 44A, 44B on the slabs 20A, 20B, where the outlet headers 44A, 44B receive the return flow of refrigerant fluid from the intermediate headers 42A, 42B. The cooled refrigerant can exit the slabs through a slab outlet 46A, 46B on the slabs 20A, 20B and flow into an outlet manifold 48. The refrigerant can then flow into an outlet refrigerant line 50 to other portions of the refrigeration system, such as the expansion device 22 described in reference to FIG. 2.

FIG. 4 is a top schematic diagram of an exemplary microchannel condenser system using multiple microchannel slabs cooled with a single fan. The slabs 20A, 20B, forming the condenser 20, can be cooled with a single condenser fan 31 of suitable size and airflow.

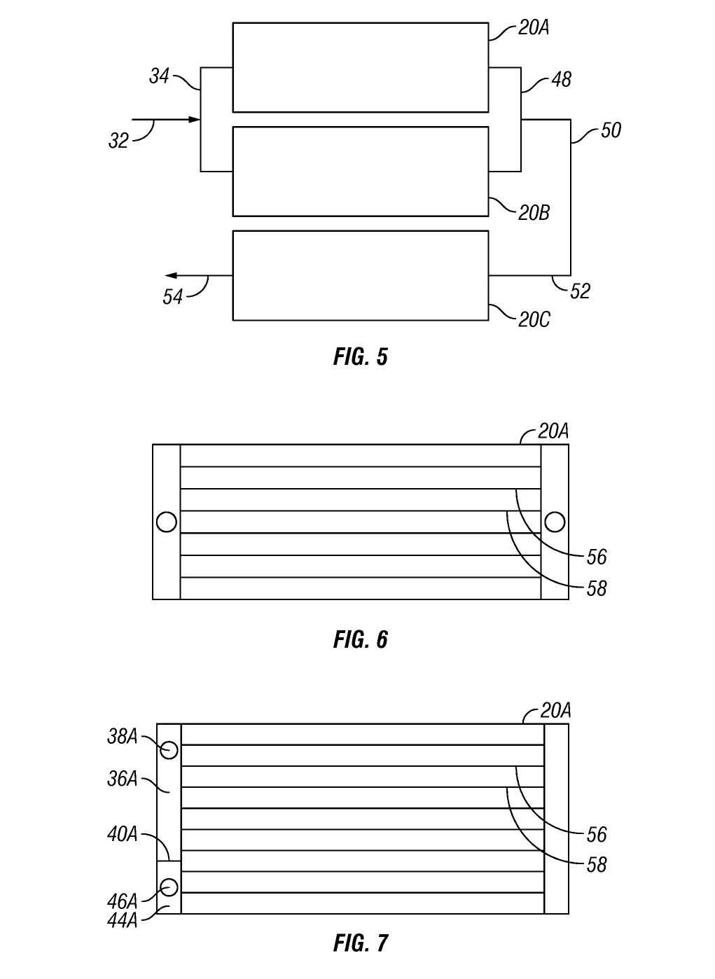

FIG. 5 is a top schematic diagram of an exemplary microchannel condenser system using multiple microchannel slabs with a parallel flow path of refrigerant in serial communication with at least one other microchannel slab. In at least one embodiment, two of the slabs can be coupled in serial flow arrangement. Thus, microchannel condenser can include multiple slabs fluidicly coupled together with at least two slabs 20A, 20B being in a parallel flow path and at least two slabs being in a serial flow path (slab 20A or 20B or a combination thereof in series with slab 20C), so that at least one of the slabs in the parallel flow path is different from at least one of the slabs in the serial flow path. An inlet refrigerant line 32 provides the heated refrigerant to the inlet manifold 34. The refrigerant flows into the slabs 20A, 20B and can flow in a single direction through the slabs to the outlet manifold 48 and into the outlet refrigerant line 50. The outlet refrigerant line 50 can provide the refrigerant to an inlet 52 of slab 20C. The refrigeration can flow in like manner through the slab 20C to an outlet 54. One fan, such as fan 32 illustrated in FIG. 4, can provide an air flow over the slabs 20A, 20B, 20C, or a portion thereof. Alternative embodiments can use multiple fans for the one or more slabs.

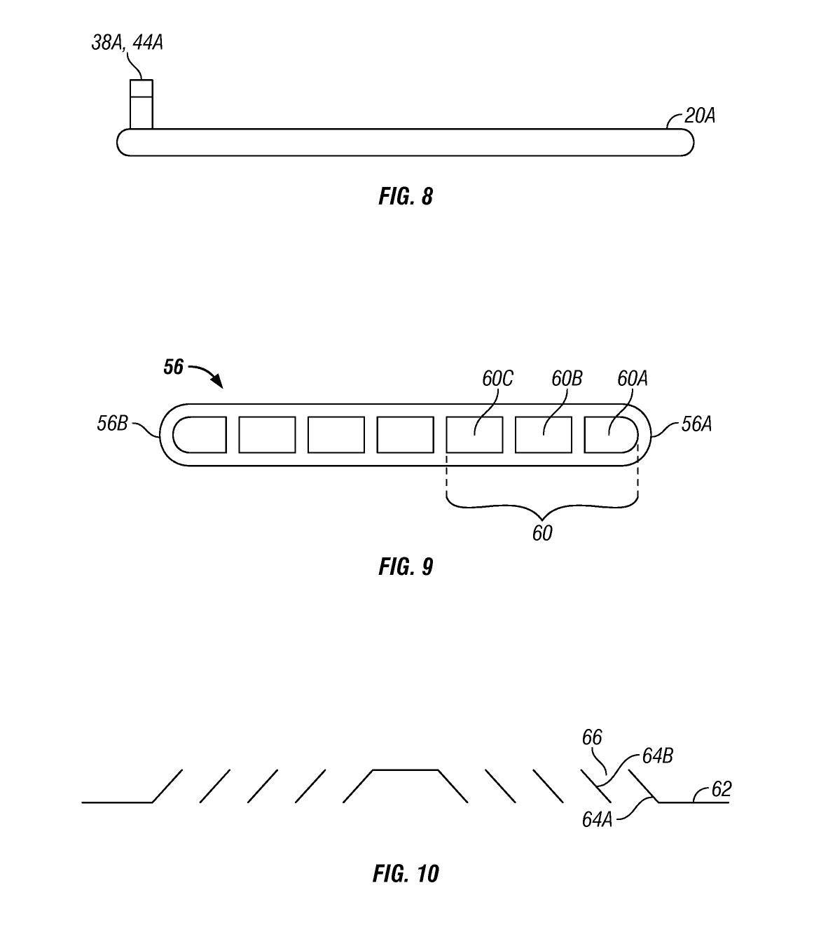

One or more of the slabs, such as slab 20A, can be designed to handle a variety of heat loads. For an exemplary cooled electronics cabinet having a design maximum heat load of 28 kilowatts, an exemplary design for at least one slab is described in FIGS. 6-9. Other sizes can be used as can be explained further. FIG. 6 is a top schematic diagram of an exemplary microchannel slab with exemplary dimensions. FIG. 7 is a top schematic diagram of an exemplary multi-path microchannel slab with exemplary dimensions for flowing multiple passes of refrigerant through the slab. FIG. 8 is a side schematic diagram of an exemplary microchannel slab. FIG. 9 is a cross-sectional schematic diagram of an exemplary microchannel tube illustrating microchannels formed in the tube. FIGS. 6-9 will be described in conjunction with each other. The tubes can be made of aluminum or other suitable thermally conductive material. An exemplary slab 20A can be formed into an approximate size of 40″ (1016 mm) long by 13.5″ (343 mm) wide. The length of the inlet, outlet, and if present the intermediate headers described above, can add additional length to the slab. In such an exemplary embodiment, the tubes 56, 58 in FIGS. 6 and 7 can be spaced a pitch distance of about 0.45″ (11 mm), so that about 31 tubes can be coupled into the exemplary slab. If the slab is a single pass slab, the slab inlet and outlet can be centrally disposed at about halfway across the width or 6.75″ (172 mm).

If the slab is a multi-pass slab, such as described in reference to FIG. 3 and further illustrated in FIG. 7, the slab inlet 38A and slab outlet 46A can be disposed about 1.5″ (38 mm) from each outside edge. The baffle 40A can be disposed about 4.5″ (114 mm) from the outside edge of the outlet header 44A to separate the inlet header 36A from the outlet header.

The thickness of the slab 20A can be about 0.78″ (20 mm), as shown in FIG. 8. A height of each microchannel tube 56, 58 is about 0.78″ (20 mm) and has a thickness of about 0.071″ (1.8 mm), as shown in FIG. 9. The slab thickness and microchannel tube height can vary depending on the cooling requirements. Another exemplary tube height can be about 1.38″ (35 mm), although lesser and greater dimensions can be used. Each tube, such as tube 56, generally includes a plurality of microchannels 60. While the size and shape of the microchannels can vary especially at the tube distal portions 56A, 56B, the microchannels can be generally about 0.043″ (1.1 mm) in cross sectional width and about 0.034″ (0.867 mm) in cross sectional height and separated by a spacing of about 0.0085″ (0.217 mm) from each other. At those sizes and spacing, about 18 microchannels can be coupled in one exemplary tube. The wall thickness on at least one of the distal portions 56A, 56B can be about 0.020″ (0.5 mm) and a side wall thickness can be about 0.014″ (0.35 mm).

FIG. 10 is a cross-sectional schematic diagram of an exemplary cooling fin that can be coupled to at least one microchannel tube. The fin 62 is generally coupled to the tube 56 described above to conduct heat away from the tube. The fin can also be made of aluminum or other suitable thermally conductive material. In at least one embodiment, the fin thickness can be about 0.005″ (0.127 mm) and can be assembled to the tube at a density of about 18 fins per inch. An advantageous fin material can be a louvered fin having a plurality of louvers 64A, 64B forming an opening 66 therebetween to allow further air flow between the louvers and increased heat dissipation from the fins. An exemplary fin material is known as 9 element fin material, although other fin materials such as 11 element fin material or unlouvered fin materials can be used.

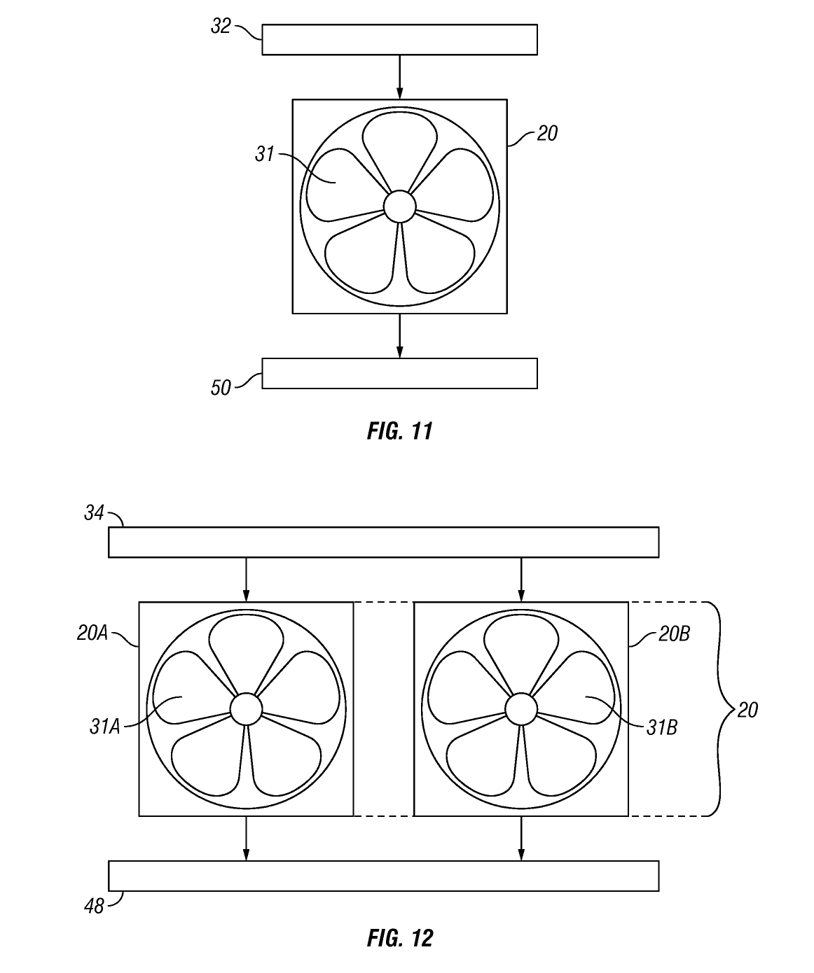

FIG. 11 is a top schematic diagram of an exemplary slab refrigeration system. The inlet refrigerant line 32 can provide refrigerant to the microchannel condenser 20, where the condenser can be formed from a single slab or multiple slabs. The refrigerant can flow through the condenser to the outlet refrigerant line 50. The condenser fan 31 can provide air flow across the condenser 20 to cool the refrigerant therein.

FIG. 12 is a top schematic diagram of an exemplary multiple slab refrigeration system in a parallel flow path with multiple condenser fans. The inlet manifold 34 can provide refrigerant to the microchannel slabs 20A, 20B which collectively form the condenser 20. The refrigerant can flow through the microchannel slabs in a parallel flow path to the outlet manifold 48. Multiple condenser fans 31A, 31B can provide air flow across the slabs 20A, 20B, respectively, to cool the refrigerant therein. Microchannel slabs 20A, 20B can further be divided into smaller slabs.

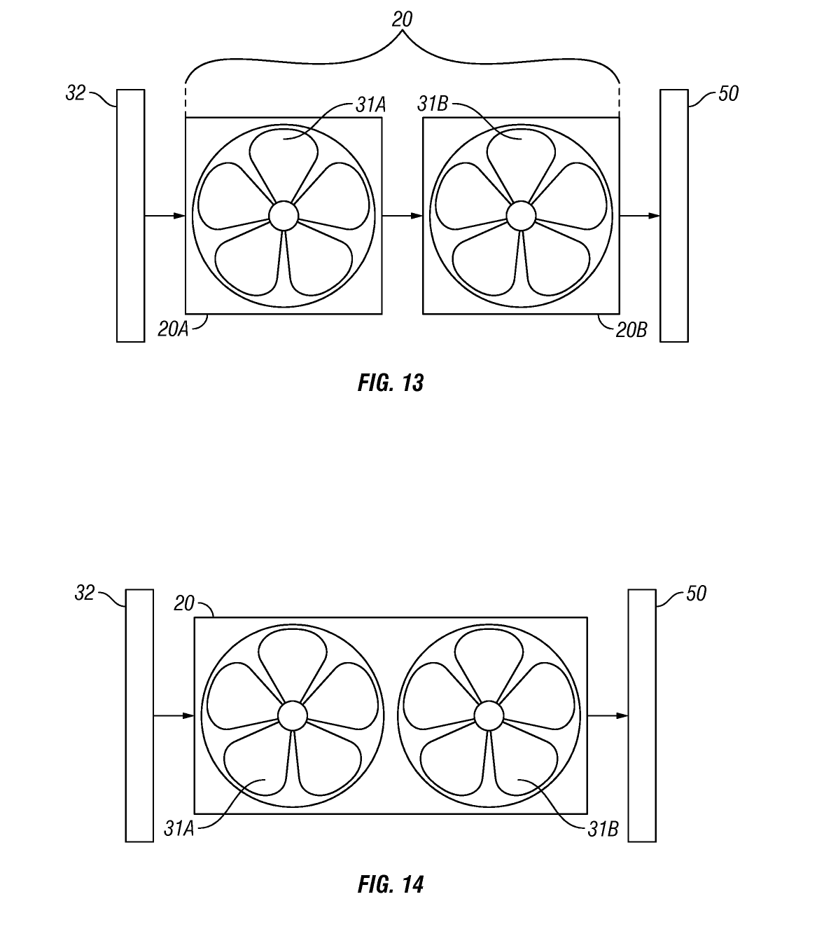

FIG. 13 is a top schematic diagram of an exemplary multiple slab refrigeration system in a serial flow path with multiple condenser fans. The inlet refrigerant line 32 can provide refrigerant to the microchannel slab 20A. The refrigerant can flow through the microchannel slab 20A and then into the microchannel slab 20B in a serial flow path to the outlet refrigerant line 50. Multiple condenser fans 31A, 31B can provide air flow across the slabs 20A, 20B, respectively, to cool the refrigerant therein.

FIG. 14 is a top schematic diagram of an exemplary slab refrigeration system with multiple condenser fans. The inlet refrigerant line 32 can provide refrigerant to the microchannel condenser 20 having an extended length compared to width. The refrigerant can flow through the condenser 20 to the outlet refrigerant line 50. Multiple condenser fans 31A, 31B can provide air flow across the condenser to cool the refrigerant therein.

The various methods and embodiments of the invention can be included in combination with each other to produce variations of the disclosed methods and embodiments, as would be understood by those with ordinary skill in the art, given the understanding provided herein. Also, various aspects of the embodiments could be used in conjunction with each other to accomplish the understood goals of the invention. Also, the directions such as “top,” “bottom,” “left,” “right,” “upper,” “lower,” and other directions and orientations are described herein for clarity in reference to the figures and are not to be limiting of the actual device or system or use of the device or system. The term “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, directly or indirectly with intermediate elements, one or more pieces of members together and can further include without limitation integrally forming one functional member with another in a unity fashion. The coupling can occur in any direction, including rotationally. Unless the context requires otherwise, the word “comprise” or variations such as “comprises” or “comprising”, should be understood to imply the inclusion of at least the stated element or step or group of elements or steps or equivalents thereof, and not the exclusion of a greater numerical quantity or any other element or step or group of elements or steps or equivalents thereof. The device or system may be used in a number of directions and orientations. Further, the order of steps can occur in a variety of sequences unless otherwise specifically limited. The various steps described herein can be combined with other steps, interlineated with the stated steps, and/or split into multiple steps. Additionally, the headings herein are for the convenience of the reader and are not intended to limit the scope of the invention.

The invention has been described in the context of various embodiments and not every embodiment of the invention has been described. Apparent modifications and alterations to the described embodiments are available to those of ordinary skill in the art. The disclosed and undisclosed embodiments are not intended to limit or restrict the scope or applicability of the invention conceived of by the Applicant, but rather, in conformity with the patent laws, Applicant intends to protect all such modifications and improvements to the full extent that such falls within the scope or range of equivalent of the following claims.

Further, any references mentioned in the application for this patent as well as all references listed in the information disclosure originally filed with the application are hereby incorporated by reference in their entirety to the extent such may be deemed essential to support the enabling of the invention. However, to the extent statements might be considered inconsistent with the patenting of the invention, such statements are expressly not meant to be considered as made by the Applicant(s).

1. A cooling system for precision cooling of electronic equipment, comprising:
an electronic equipment support structure adapted to support one or more heat generating electronic devices;
an evaporator in fluid communication with the support structure and adapted to provide cooling to the support structure;
a compressor; and
a microchannel condenser fluidicly coupled to the compressor and adapted to cool refrigerant from the compressor and dissipate heat from the cooling system.

2. The system of claim 1, wherein the microchannel condenser comprises multiple slabs fluidicly coupled together.

3. The system of claim 1, wherein the microchannel condenser comprises multiple slabs fluidicly coupled together with at least two slabs in a parallel flow path.

4. The system of claim 1, wherein the microchannel condenser comprises multiple slabs fluidicly coupled together with at least two slabs in a serial flow path.

5. The system of claim 1, wherein the microchannel condenser comprises multiple slabs fluidicly coupled together with at least two slabs in a parallel flow path and at least two slabs in a serial flow path, wherein at least one of the slabs in the parallel flow path is different from at least one of the slabs in the serial flow path.

6. The system of claim 1, wherein the microchannel condenser comprises multiple slabs fluidicly coupled together, the multiple slabs being cooled by a single condenser fan.

7. The system of claim 1, wherein the microchannel condenser comprises louvered fins.

8. A method of precision cooling of electronic equipment, comprising:
flowing a quantity of refrigerant through an evaporator to cool heat generating electronic devices supported in an electronic equipment support structure;
compressing the refrigerant through a compressor;
cooling the refrigerant through a microchannel condenser; and
flowing a quantity of fluid across fins in the microchannel condenser.

9. The method of claim 8, wherein cooling the refrigerant through a microchannel condenser comprises flowing the refrigerant through multiple slabs fluidicly coupled together.

10. The method of claim 8, wherein flowing the refrigerant through multiple slabs fluidicly coupled together comprises flowing the refrigerant in a parallel flow path through at least two slabs.

11. The method of claim 8, wherein flowing the refrigerant through multiple slabs fluidicly coupled together comprises flowing the refrigerant in a serial flow path through at least two slabs.

12. The method of claim 8, wherein flowing the refrigerant through multiple slabs fluidicly coupled together comprises flowing the refrigerant in a parallel flow path through at least two slabs and flowing the refrigerant in a serial flow path through at least two slabs, wherein at least one of the slabs in the parallel flow path is different from at least one of the slabs in the serial flow path.

13. The method of claim 8, wherein cooling the refrigerant through a microchannel condenser comprises flowing the refrigerant through multiple slabs fluidicly coupled together and cooling the condenser with a single condenser fan.

14. The method of claim 8, wherein flowing air across fins in the microchannel condenser comprises flowing the air through louvered fins.
